(19) United States
(12) Patent Application Publication
(10) Pub. No.: US 2025/0210548 A1
(43) Pub. Date: Jun. 26, 2025

(54) EMBEDDED VOLTAGE REGULATION MODULE

(71) Applicant: Chipletz, Inc., Spicewood, TX (US)

(72) Inventors: Siddharth Ravichandran, Austin, TX (US); Michael Su, Austin, TX (US); Michael Alfano, Austin, TX (US); Bryan Black, Austin, TX (US)

(73) Assignee: Chipletz, Inc., Spicewood, TX (US)

(21) Appl. No.: 18/960,385

(22) Filed: Nov. 26, 2024

Related U.S. Application Data
(63) Continuation-in-part of application No. 18/773,010, filed on Jul. 15, 2024.
Application No. 18/773,010 is a division of application No. 17/692,587, filed on Mar. 11, 2022, now Pat. No. 12,288,756.
(63) Continuation-in-part of application No. 18/378,235, filed on Oct. 10, 2023.
(63) Continuation-in-part of application No. 18/132,336, filed on Apr. 7, 2023.
(63) Continuation-in-part of application No. 18/138,050, filed on Apr. 22, 2023.
(63) Continuation-in-part of application No. 18/206,933, filed on Jun. 7, 2023.
(63) Continuation-in-part of application No. 18/429,374, filed on Jan. 31, 2024.
(63) Continuation-in-part of application No. 18/754,504, filed on Jun. 26, 2024.
(63) Continuation of application No. 18/773,795, filed on Jul. 16, 2024.
(60) Provisional application No. 63/414,778, filed on Oct. 10, 2022.
(60) Provisional application No. 63/334,449, filed on Apr. 25, 2022.
(60) Provisional application No. 63/349,920, filed on Jun. 7, 2022.
(60) Provisional application No. 63/442,438, filed on Jan. 31, 2023.
(60) Provisional application No. 63/570,299, filed on Mar. 27, 2024.

(51) Int. Cl. H01L 23/64; H01L 23/00; H01L 23/498; H01L 25/16; H10D 1/00; H10D 1/68

(52) U.S. Cl. CPC H01L 23/642; H01L 23/49816; H01L 23/49822; H01L 23/49838; H01L 25/16; H10D 1/042; H10D 1/043; H10D 1/716; H01L 24/16; H01L 2224/16235

(57) ABSTRACT

A fully-integrated voltage regulation module is fabricated into a single, unitary tile. After tile testing, a selected set of good tiles is fabricated into a single, monolithic substrate in accordance with a selected layout. After substrate testing, the good substrate is then fabricated into a single advanced package.

### CROSS-REFERENCE TO RELATED APPLICATIONS

This application is:
1. a Continuation-In-Part of U.S. patent application Ser. No. 18/773,010, filed 15 Jul. 2024 (“First Divisional Application”), which is a divisional application of U.S. patent application Ser. No. 17/692,587, filed 11 Mar. 2022 (“First Patent Application”);
2. a Continuation-In-Part of U.S. patent application Ser. No. 17/829,252, filed 31 May 2022 (“Second Patent Application”);
3. a Continuation-In-Part of U.S. patent application Ser. No. 18/132,336, filed 7 Apr. 2023 (“Third Patent Application”);
4. a Continuation-In-Part of U.S. patent application Ser. No. 18/138,050, filed 22 Apr. 2023 (“Fourth Patent Application”), which claims the benefit of U.S. Provisional Patent Application Ser. No. 63/334,449, filed 25 Apr. 2022 (“First Provisional Application”);
5. a Continuation-In-Part of U.S. patent application Ser. No. 18/206,933, filed 7 Jun. 2023 (“Fifth Patent Application”), which claims the benefit of U.S. Provisional Patent Application Ser. No. 63/349,920, filed 7 Jun. 2022 (“Second Provisional Application”);
6. a Continuation-In-Part of U.S. patent application Ser. No. 18/378,235, filed 10 Oct. 2023 (“Sixth Patent Application”), which claims the benefit of U.S. Provisional Patent Application Ser. No. 63/414,778, filed 10 Oct. 2022 (“Third Provisional Application”);
7. a Continuation-In-Part of U.S. patent application Ser. No. 18/429,374, filed 31 Jan. 2024 (“Seventh Patent Application”), which claims the benefit of U.S. Provisional Patent Application Ser. No. 63/442,438, filed 31 Jan. 2023 (“Fourth Provisional Application”);
8. a Continuation-In-Part of U.S. patent application Ser. No. 18/754,504, filed 26 Jun. 2024 (“Eighth Patent Application”), which claims the benefit of U.S. Provisional Patent Application Ser. No. 63/570,299, filed 27 Mar. 2024 (“Fifth Provisional Application”); and
9. a Continuation-In-Part of U.S. patent application Ser. No. 18/773,795, filed 16 Jul. 2024 (“Ninth Patent Application”), collectively referred to hereinafter as the “Related Applications”.

This application claims priority to the Related Applications, and hereby claims benefit of the filing dates thereof pursuant to 37 C.F.R. § 1.78 (a).

The subject matter of the Related Applications, each in its entirety, is expressly incorporated herein by reference.

### FIELD OF INVENTION

The present invention relates to the field of integrated circuits. More particularly, it relates to methods to fabricate a fully-integrated voltage regulation facility, and to voltage regulation facilities so fabricated.

### BACKGROUND

In general, in the descriptions that follow, the first occurrence of each special term of art that should be familiar to those skilled in the art of integrated circuits (“ICs”) and systems will be italicized. In addition, when a term that may be new or that may be used in a context that may be new, that term will be set forth in bold and at least one appropriate definition for that term will be provided.

Hereinafter, reference to a facility shall mean a circuit or an associated set of circuits adapted to perform a particular function regardless of the physical layout of an embodiment thereof. Thus, the electronic elements comprising a given facility may be instantiated in the form of a hard macro adapted to be placed as a physically contiguous facility, or in the form of a soft macro the elements of which may be distributed in any appropriate way that meets speed path requirements. In general, electronic systems comprise many different types of facilities, each adapted to perform specific functions in accordance with the intended capabilities of each system. Depending on the intended system application, the several facilities comprising the hardware platform may be integrated onto a single IC, or distributed across multiple ICs. Depending on cost and other known considerations, the electronic components, including the facility-instantiating IC(s), may be embodied in one or more single- or multi-chip tiles/substrates/packages. However, unless expressly stated to the contrary, the form of instantiation of any facility shall be considered as being purely a matter of design choice.

Hereinafter, when we refer to a module, we shall mean an instantiation of one or more facilities into a single, unitary, physical structure. By way of example, we consider singulated die to be modules, whether as singulated or as might be embedded within a larger, unitary structure such as a tile adapted for use within a package.

In the field of advanced packaging, it is known that different system facilities often require different voltages, and that those respective voltages must be closely regulated as a function of the instantaneous current consumption of the respective facility. In the past, various voltage regulation (“VR”) facilities have been proposed to satisfy these requirements, with greater or lesser success. One particular problem is the physical dimensions of these prior-art devices. One further problem is the typical requirement that the VR components be separated, physically, from the system facility being supported.

In our First Divisional Application and First Patent Application, we described a method for fabricating a semiconductor package having integrated capacitors. In particular, we described how to fabricate thin-film capacitors, and then to embed them within a semiconductor package. As is known, capacitors comprise essential components of most VR facilities. As we will show, hereinafter, these particular capacitors are especially useful in a fully-integrated VR facility.

In our Second Patent Application, we describe a method to directly attach multiple dies of different heights to a substrate with embedded components along with methods to get a flat top side for better thermal management. This is important for attaching dies to substrates with a fully-integrated VR facility.

In our Third Patent Application, we described methods to co-package photonics with substrates having embedded components.

In our First Provisional Application and Fourth Patent Application, we described a method for fabricating thru-package vertical interconnects. As we will show, hereinafter, these particular interconnect structures may be used effectively in a fully-integrated VR facility.

In our Second Provisional Application and Fifth Patent Application, we described a method for fabricating inductors suitable for embedding in a package substrate. In particular, we noted that such inductors were especially well adapted for use in a fully-integrated VR facility. For example, in Paragraph [025] of the Second Provisional Application, we noted:
“This disclosure relates to inductor(s) embedded in a package substrate or board. These inductors may be used in power delivery (DC-DC conversion) or other filtering applications. These inductors may be integrated in the AC/DC substrate, which refers to a semiconductor package substrate that:
   May have a fine-pitch routing layers (primarily for interconnecting dies on top)
   May have a few coarse-pitch layers (primarily for power/IO connections to board)
   Embedded device(s) in core (Capacitors, inductors, power/RF/digital/photonic dies etc. for filtering power noise, convert & regulate voltage, assist die-to-die communication, etc.)” (Emphasis added.)

Further, in Para [44], we noted:
“In another version of this, the power management IC (or any IC) may be embedded in another trench in the capacitor to form a thin-film embedded voltage regulator module where the terminal metals may be used to form the necessary connections.” (Emphasis added.)

In our Third Provisional Application and Sixth Patent Application, we described a method for mitigating cracks is semiconductor packages. In particular, we submit that it should be clear to those skilled in this art that such methods are well adapted for use in a fully-integrated VR facility.

In our Fourth Provisional Application and Seventh Patent Application, we described alternative methods for fabricating thin-film capacitors with improved Equivalent Series Resistances well adapted for use in fully-integrated VR facilities.

In our Fifth Provisional Application and Eighth Patent Application, we described methods for mitigating cross-talk in semiconductor packages. In particular, we submit that it should be clear to those skilled in this art that such methods are well adapted for use in a fully-integrated VR facility.

In our Ninth Patent Application, we described methods for improving yields of advanced packages. In particular, we noted that the disclosed tile-based methods are adapted for use with fully-integrated VR facilities. For example, in lines 5-6 of Para [012] (and FIG. 1), we noted that the “fourth tile 108 comprises a power facility’; and then, in lines 11-12, we noted that “the power facility may comprise one or more capacitors, voltage regulator dies and other passive components”. (Emphasis added.)

In the present application, we will now describe, in detail, how the several inventions embodied in our prior Provisional and Patent Applications can be combined to fabricate a fully-integrated, embedded VR module (“eVRM”).

However, before doing so, we will discuss the most relevant prior art known to us at this time, namely, the publication: “FIVR-Fully Integrated Voltage Regulators on 4th Generation Intel® Core™ SoCs”, E. A. Burton, et al., in Proc. 29th Annu. IEEE Applied Power Electronics Conf., 2014 (“Burton”). We first note that the authors describe the image comprising FIG. 1 (b) as: “A simplified schematic for a two phase VR domain”. They then add: “The power FETs, control circuitry and high frequency decoupling are on the die, while the inductors and mid-frequency input decoupling capacitors are placed on the package.” (Emphasis added.) Thus, the authors have made it clear, expressly, that this embodiment does not represent a “fully-integrated voltage regulator”, at least with respect to its being “fully-integrated” in a form suitable for implementation in a single tile such as we described in our Seventh Patent Application. We note that, in the FIVR technology, the term “fully-integrated” is a bit misleading in that the VR circuitry is integrated directly onto the processor die mounted on the package substrate, while some of the passive components are embedded within the package substrate.

In Burton, the authors described the problem sought to be solved by the FIVR design as follows:
“A limitation of power gate is that all active domains still operate at the highest voltage required by any individual domain. To create separate voltage domains an entirely new regulator must be added to the motherboard, which adds cost, increases area, and requires extra package pins. An improvement suggested by recent research is the integration of high frequency buck regulators directly on the microprocessor package, or in the die itself [2] [3] [4] [5]. This allows a much larger number of independent power domains, each managed dynamically to match the local computational demand. For example, this would allow one CPU core to run at an elevated voltage and frequency to satisfy a heavy computational load, while other cores execute lower priority code at a much lower voltage and frequency to save power.” See, Burton, pg. 1, col. 2, second paragraph.
   and the expected benefits of this design were described as follows:
“The benefit categories were: battery life increase, increased available power (for increased burst performance), decreased power required for a given level of performance (or almost equivalently, increased performance for a given power consumed), decreased platform cost and size, improved product flexibility and scalability.” See, Burton, pg. 2, col. 1, line 32-col. 2, line 4.

According to the authors:
“The key to making FIVR affordable was integrating the power devices directly into the microprocessor die.” See, Burton, pg. 4, col. 1, lines 21-22.

While FIVR addresses the challenge of delivering a higher voltage into the package, we submit that it introduces unnecessarily complex routing, making the solution limited to niche applications and unsuitable for high-current power domains. Additionally, we note that FIVR can only be fully tested once the entire package assembly is complete, and, if one or more of the FIVR facilities is found to be defective, the entire package must be scrapped.

Insofar as we are aware, the FIVR technology was first implemented in the Haswell architecture, introduced in June 2013. (See, https://en.wikipedia.org/wiki/Haswell_(microarchitecture)). Further, it appears that this technology was still being used by Intel as late as about November 2017. (See, https://xdevs.com/pow/fivr_pow/). So, we submit that, at least as far as Intel microprocessor designers were concerned in 2017, their “partially-integrated” FIVR design was still fully satisfactory.

We respectfully disagree. We submit that the claimed benefits of the FIVR technology, quoted above, can be realized by other means. Further, we submit that such other means need to realize even more significant benefits not possible with the FIVR technology.

Today, there is a performance cap on devices manufactured in the United States of America that can be sold to China. This can be achieved by limiting the power supply to the target silicon through the board. However, it may be possible to circumvent this ban by desoldering the silicon or interposer complex (ASIC+HBM) package from the board or mezzanine card and mounting it on a different board. As is known, desoldering is generally feasible at the board level. However, when power delivery is “built into” the package substrate, desoldering becomes very difficult if not impossible since it is currently not possible to desolder the dies from the substrate without damaging the dies. While desoldering silicon is possible with C4 or Solder Ball interfaces, advanced systems subject to export regulations today typically use microbump or hybrid bonding. We submit that means for permanently constraining the VR facility are needed.

### BRIEF SUMMARY OF THE INVENTION

According to a generic embodiment, a voltage regulation module comprises:
a first capacitor having a first terminal and a second terminal, the first capacitor having:
   a predetermined first dimension, X₁, in a first dimension, x, and
   a predetermined second dimension, Y₁, in a second dimension, y, substantially orthogonal to the first dimension;
a semiconductor die comprising a voltage regulation control facility having an input terminal connected to the first terminal of the first capacitor and an output terminal, the die comprising a plane of predetermined thickness and having:
   a predetermined third dimension, X₂, in the x dimension,
   a predetermined fourth dimension, Y₂, in the y dimension,
   a first side, and
   a second side;
an inductor having a first terminal connected to the output terminal of the semiconductor die and a second terminal, the inductor having
   a predetermined fifth dimension, X₃, in the x dimension, and
   a predetermined sixth dimension, Y₃, in the y dimension; and
a second capacitor having a first terminal connected to the output terminal of the inductor and
   a second terminal, the first capacitor having
   a predetermined seventh dimension, X₄, in the x dimension, and
   a predetermined eighth dimension, Y₄, in the y dimension;
characterized in that:
   the first capacitor is adapted to be located on a selected one of the first and second sides of the semiconductor die,
   the inductor is adapted to be located on a selected one of the first and second sides of the semiconductor die, and
   the second capacitor is adapted to be located on a selected one of the first and second sides of the semiconductor die;
wherein:
   X₂ is no greater than X₁;
   X₃ is no greater than X₁; and
   X₄ is no greater than X₁; and
wherein, in a genus comprising at least four species:
   in a selected first one of said species:
      Y₂ is no greater than Y₁;
      Y₃ is no greater than Y₁; and
      Y₄ is no greater than Y₁;
   in a selected second one of said species:
      Y₁ is no greater than Y₂;
      Y₃ is no greater than Y₂; and
      Y₄ is no greater than Y₂;
   in a selected third one of said species:
      Y₁ is no greater than Y₃;
      Y₂ is no greater than Y₃; and
      Y₄ is no greater than Y₃; and
   in a selected fourth one of said species:
      Y₁ is no greater than Y₄;
      Y₂ is no greater than Y₄; and
      Y₃ is no greater than Y₄.

In a first species embodiment of the voltage regulation module:
Y₂ is no greater than Y₁;
Y₃ is no greater than Y₁; and
Y₄ is no greater than Y₁.

In a second species embodiment of the voltage regulation module:
Y₁ is no greater than Y₂;
Y₃ is no greater than Y₂; and
Y₄ is no greater than Y₂.

In a third species embodiment of the voltage regulation module:
Y₁ is no greater than Y₃;
Y₂ is no greater than Y₃; and
Y₄ is no greater than Y₃.

In a fourth species embodiment of the voltage regulation module:
Y₁ is no greater than Y₄;
Y₂ is no greater than Y₄; and
Y₃ is no greater than Y₄.

### BRIEF DESCRIPTION OF THE SEVERAL VIEWS OF THE DRAWINGS

FIG. 1 illustrates, is stylized circuit diagram form, an eVRM constructed in accordance with one embodiment of our invention.

FIG. 2, comprising FIGS. 2A and 2B, illustrates, in stylized cross-section view, two possible configurations of a non-size constrained eVRM adapted for embedding into an integrated package substrate;

FIG. 3, comprising FIGS. 3A, 3B, 3C, 3D and 3E, illustrates, in stylized cross-section view, five possible configurations of a size constrained e VRM adapted for embedding into an integrated package substrate;

FIG. 4, comprising FIGS. 4A, 4B, 4C and 4D, illustrates, in stylized cross-section view, four alternative embodiments of e VRM that have been fabricated with EMI shielding;

FIG. 5 illustrates, in stylized cross-section view, one possible embodiment of a multi-e VRM module adapted for embedding into an integrated package substrate;

FIG. 6 illustrates, in stylized cross-sectional view, one possible embodiment of the multi-eVRM module illustrated in FIG. 5 after fabrication into a fully functional advanced package;

FIG. 7, comprising FIGS. 7A, 7B and 7C, illustrates, in stylized cross-section view, three possible embodiments of eVRM integrated into advanced packages;

FIG. 8, comprising FIGS. 8A, 8B, 8C and 8D, illustrates, in stylized cross-section view, four other embodiments of eVRM integrated into advanced packages;

FIG. 9 illustrates, in stylized plan view, an embodiment of an eVRM in which the several components, active and passive, are embedded side-by-side within cavities formed in a sheet of passive material, e.g., thin-film capacitor or inductor sheet;

FIG. 10, comprising FIGS. 10A, 10B and 10C, illustrates, in stylized cross-section view, three possible embodiments of silicon-based e VRM;

FIG. 11, comprising FIGS. 11A, 11B, 11C and 11D, illustrates, in stylized cross-section view, four other embodiments of silicon-based eVRM;

FIG. 12, comprising FIGS. 12A, 12B, 12C, 12D and 12E, illustrates, in stylized cross-section view, four possible embodiments of eVRM fabricated using a generic double-sided molding process;

FIG. 13, comprising FIGS. 13A, 13B, 13C and 13D, depicts the process flow illustrated in FIG. 4 of the Ninth Patent Application in which e VRM fabricated in accordance with our invention are embedded in the course of manufacturing an advanced package substrate;

FIG. 14, comprising FIGS. 14A and 14B, illustrates possible embodiments of stand-alone, deep trench silicon capacitors adapted to be embedded into an advanced package substrate; and

FIG. 15, comprising FIGS. 15A, 15B, 15C and 15D, illustrate one possible process for fabricating the deep trench silicon capacitors illustrated in FIG. 14.

### DETAILED DESCRIPTION

The following description provides different embodiments for implementing aspects of the present invention. Specific examples of components and arrangements are described below to simplify the explanation. These are merely examples and are not intended to be limiting. For example, the description of a first component coupled to a second component includes embodiments in which the two components are directly connected, as well as embodiments in which an additional component is disposed between the first and second components. In addition, the present disclosure repeats reference numerals in various examples. This repetition is for the purpose of clarity and does not in itself require an identical relationship between the embodiments.

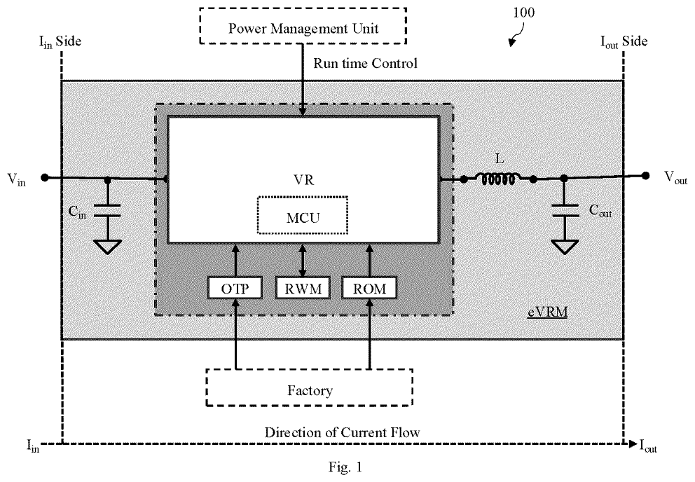

FIG. 1 illustrates, in stylized circuit diagram form, an eVRM 100 constructed in accordance with one embodiment of our invention. As in a conventional buck converter, eVRM 100 comprises an input filter capacitor, Cᵢₙ, a voltage regulation facility, VR, an output inductor, L, and an output filter capacitor, Cₒᵤₜ. In operation, the eVRM 100 receives input current, Iᵢₙ, at a predetermined input voltage, Vin, from an external current source (not shown), and delivers an output current, Lout, at a selected output voltage, Vout, to an external current sink (not shown), e.g., a current consuming circuit module on a target die. Note that, in the illustrated embodiment, eVRM 100 is configured to receive Iᵢₙ via a respective Iᵢₙ Side of the physical module, and to product Iₒᵤₜ via a respective Iₒᵤₜ Side of the module. We shall hereinafter demonstrate that this “flow-through” characteristic is particularly well adapted for embedding our e VRM 100 into an advanced package.

In the illustrated embodiment, we have integrated a number of important enhancements adapted substantially to improve the efficiency and effectiveness of our eVRM 100:
First, we have integrated a microcontroller, MCU, on the same die as the VR facility, to provide the eVRM 100 with programmability of operating characteristics. For example, the MCU may be programmed to provide a preset voltage regulation for a standardized task/workload where the V & I demand curves of the current sink is very well known. Also, by way of example, the MCU may be programmed to provide a regulated voltage that anticipates the demand of the current sink. This predictive capability enables the e VRM 100 to forecast voltage droop and to adjust the buck frequency or Iₒᵤₜ accordingly.
Second, we have integrated a read-only memory, ROM, adapted to store, at the factory during the die manufacturing process, a computer program adapted to be executed by the MCU to control the run-time operation of the eVRM 100 in accordance with power-up and run-time control commands issued by an external power management unit, PMU.
Third, we have provided a read-write memory, RWM, adapted to store, during run-time, one or more variables that represent not just desired operating parameters issued by the PMU for the eVRM 100, but also run-time performance data calculated by the MCU for output, on an as-requested basis, to the PMU.
Fourth, we have integrated a one-time-programmable memory, OTP, adapted to store one or more fixed operational constraints that represent hard, invariable restrictions on the ability of the MCU to vary the operating characteristics of the eVRM 100. By way of example of one such constraint, consider an embodiment of the eVRM 100 that is capable of supplying 200 amps of current at a target Vout of 0.7 volts. While this configuration may be fully approved for use in systems offered for sale in the manufacturer's legal jurisdiction, this configuration may be approved for export to one or more foreign jurisdictions if and only if the Lout current is permanently constrained to, say, no greater than 160 amps. The inclusion of this constraint function may significantly expand the worldwide market for such eVRM.

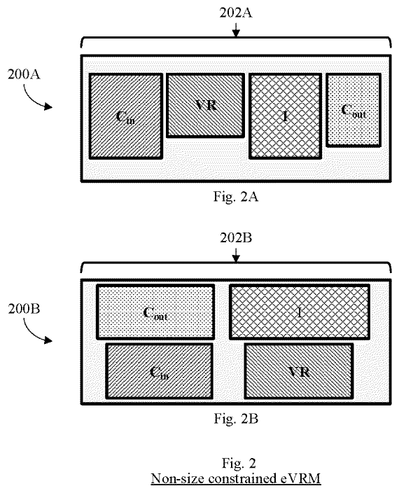

FIG. 2, comprising FIGS. 2A and 2B, illustrates, in stylized cross-section view, two possible configurations of a non-size constrained eVRM adapted for embedding into an integrated package substrate. In FIG. 2A, we have depicted one possible configuration of a non-size constrained eVRM 200A, in which all of the circuit components, including the active and passive elements, are arranged in a substantially planar configuration. In FIG. 2B, we have depicted one possible configuration of yet another non-size constrained eVRM 200B, in which all of the circuit components, including the active and passive elements, are arranged in a multi-planar configuration. We recognize that other configurations are also possible whenever the X/Y footprint 202[A::B] of the eVRM 200[A::B] with respect to the primary plane of the substrate is not constrained.

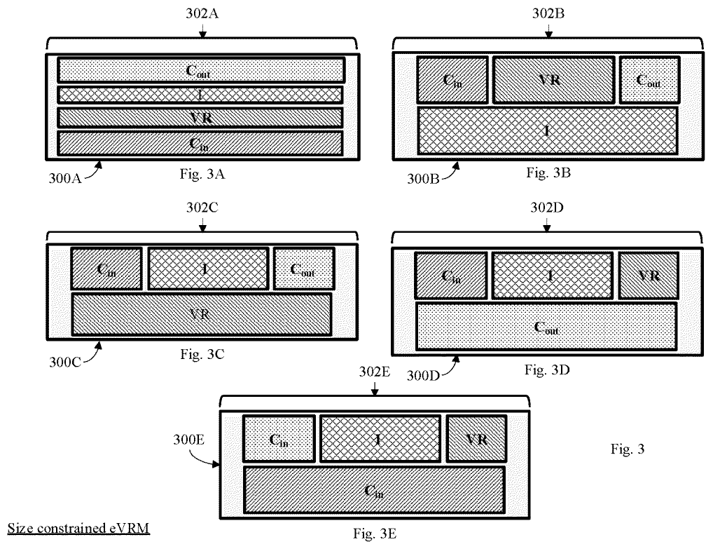

FIG. 3, comprising FIGS. 3A, 3B, 3C, 3D and 3E, illustrates, in stylized cross-section view, five possible configurations of a size constrained eVRM adapted for embedding into an integrated package substrate. In FIG. 3A, we have depicted one possible configuration of a size constrained eVRM 300A, in which all of the circuit components (each of which happen to have substantially identical X/Y footprint), including the active and passive elements, are arranged in a single stack configuration. In FIG. 3B, we have depicted one possible configuration of yet another size constrained eVRM 300B, in which the X/Y footprint of the I component constrains the configuration. In FIG. 3C, we have depicted one possible configuration of still another size constrained eVRM 300C, in which the X/Y footprint of the VR component constrains the configuration. In FIG. 3D, we have depicted one possible configuration of one other size constrained eVRM 300B, in which the X/Y footprint of the Cₒᵤₜ component constrains the configuration. Finally, in FIG. 3E, we have depicted one possible configuration of a size constrained eVRM 300E in which the X/Y footprint of the Cᵢₙ component constrains the configuration. We recognize that other configurations are also possible whenever the X/Y footprint 302[A::E] of the eVRM 300[A::E] with respect to the primary plane of the substrate is constrained. We submit that one significant advantage of imposing size constraints on an eVRM configuration is to better match the X/Y shadow footprint of the target current sink. For example, in a situation where the target current sink has a relatively small X/Y shadow footprint, then the configuration of the eVRM can be size-constrained to minimize any X/Y dimensional differences between the sink and the respective eVRM, thereby facilitating locating the eVRM “beneath” (or “in the shadow of”) the target sink in the finished package.

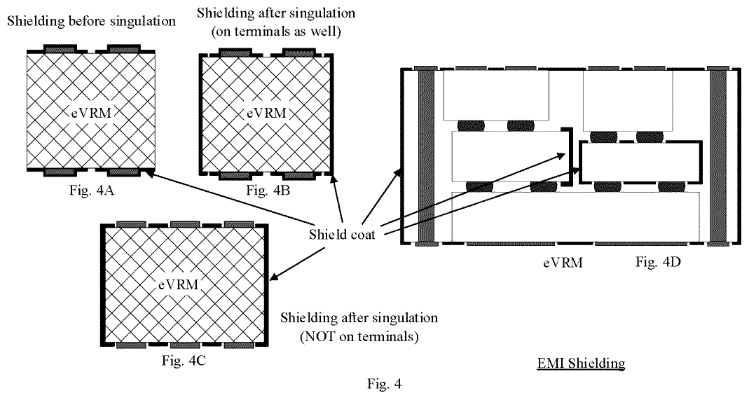

We are aware of at least two challenges to creating an e VRM adapted to be dropped into a cavity formed in the substrate is: first, the EMI noise from the eVRM affecting any high-speed signaling on the package; and two, the noise from other devices in the package may shift the optimal operating point of the eVRM. In accordance with one embodiment of our invention, in FIG. 4, we have illustrated possible processes for coating the eVRM for EMI shielding prior to embedding. By way of example, such EMI shielding can comprise a metallic coating to create a Faraday cage around the eVRM. Suitable coating methods include: sputtering or PVD; CVD; and a spray coat comprising conductive inks. The shield coating can be performed: during manufacturing of the eVRM, e.g., within the layers; prior to dicing; after dicing and before embedding; or after embedding inside the cavity but before cavity fill. In FIG. 4A, we have illustrated an eVRM on which the shield coat has been applied before singulation. In FIG. 4B, we have illustrated an eVRM on which the shield coat has been applied after singulation, including on the terminals as well. In FIG. 4C, we have illustrated an eVRM on which the shield coat has been applied after singulation, but not on the terminals. In FIG. 4D, we have illustrated an e VRM on which the shield coat has been applied to several selected surfaces of the internal components of the eVRM, as well as on all external surfaces except the terminals. We submit that experience will be gained during design, fabrication and testing of various e VRM in the selection of the form and configuration of EMI shielding appropriate for each design.

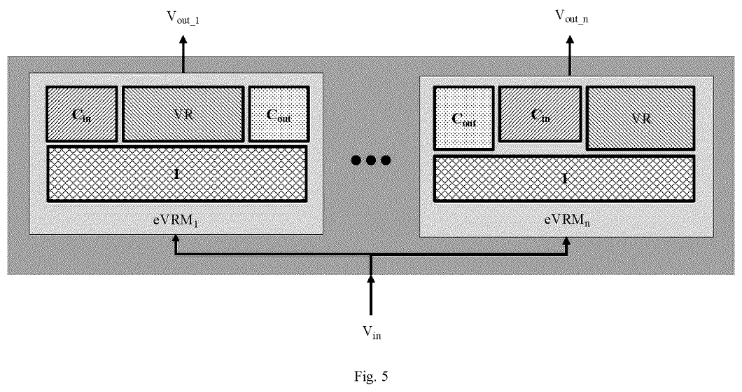

In FIG. 5, we have illustrated one possible embodiment of a multi-eVRM module comprising a plurality, n, of physically separate and independently operating eVRM. We have intentionally depicted the eVRM₁ differently from the eVRMₙ to clearly indicate that each of the n eVRM can be selected to support different current sinks having different power requirements. One possible process for fabricating a multi-e VRM module is to first fabricate and test each of the desired eVRM, select only good eVRM for sub-assembly into the multi-eVRM module, and the perform final test of the assembled module. We believe that it may be possible in some embodiments of our multi-e VRM module to improve the “fit” of the several eVRM within the shadows of very small power domains on the current sink die.

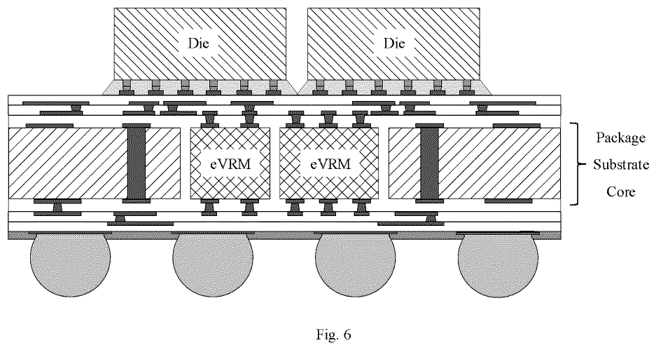

By way of example, FIG. 6 illustrates, in stylized cross-sectional view, one possible embodiment of the multi-e VRM module illustrated in FIG. 5 after fabrication into a fully functional advanced package.

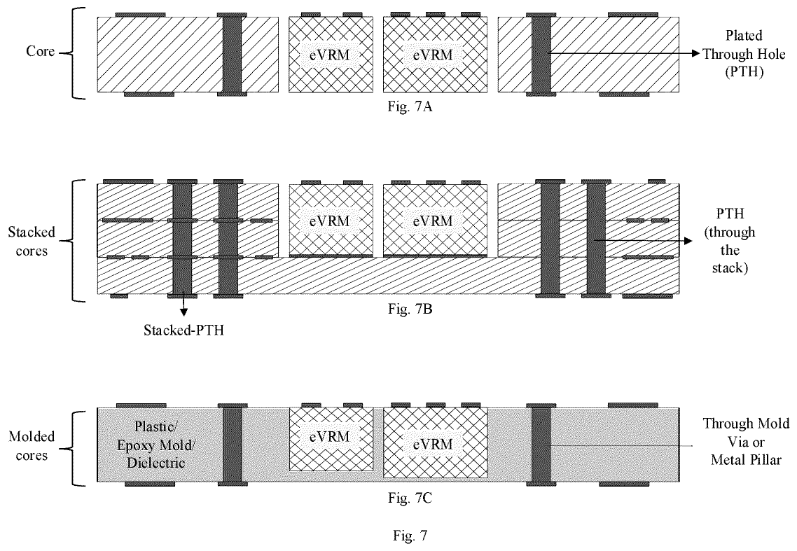

In FIG. 7, comprising FIGS. 7A, 7B and 7C, we have illustrated, in stylized cross-section view, three possible embodiments of multi-eVRM modules adapted for integration into advanced packages.

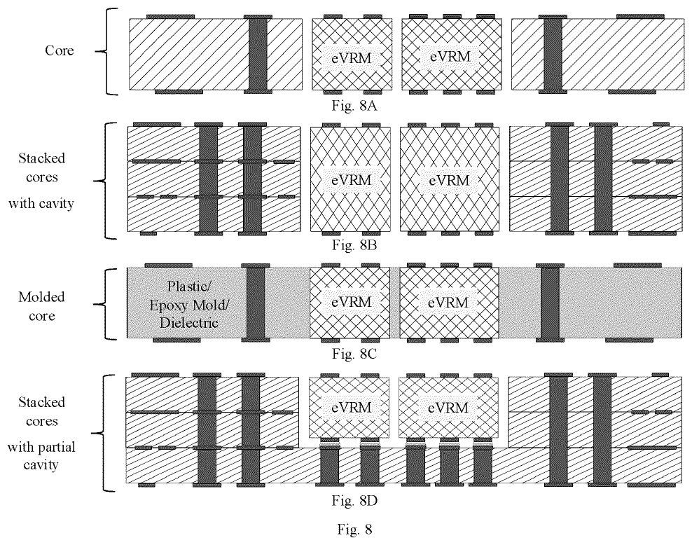

In FIG. 8, comprising FIGS. 8A, 8B, 8C and 8D, we have illustrated, in stylized cross-section view, four additional possible embodiments of multi-eVRM modules adapted for integration into advanced packages.

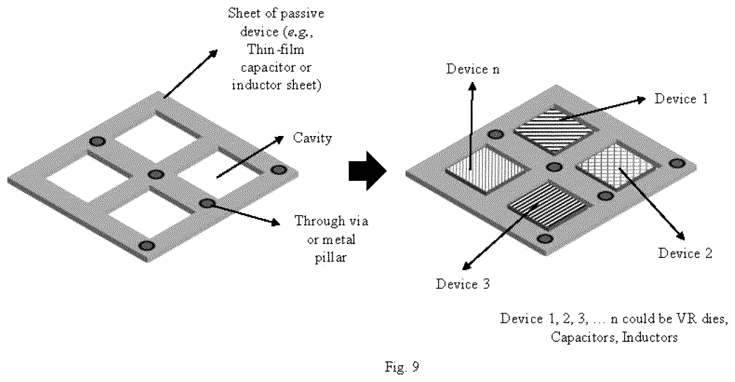

FIG. 9 illustrates, in stylized plan view, an embodiment of an eVRM in which the several components, active and passive, are embedded side-by-side within cavities formed in a sheet of passive material, e.g., thin-film capacitor or inductor sheet.

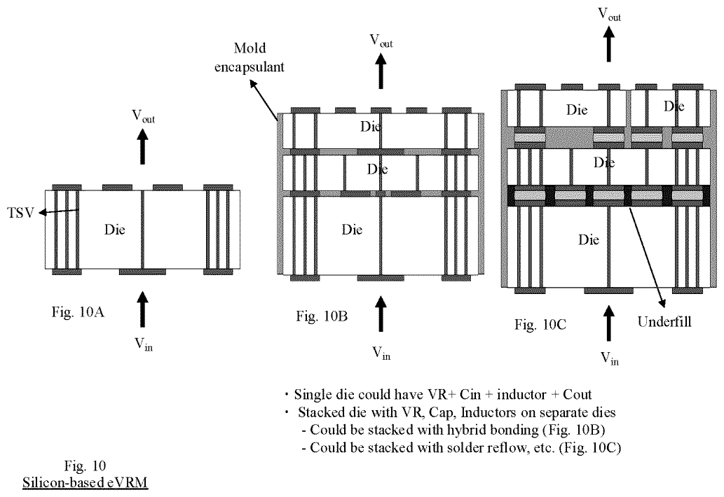

FIG. 10, comprising FIGS. 10A, 10B and 10C, illustrates, in stylized cross-section view, three possible embodiments of silicon-based e VRM.

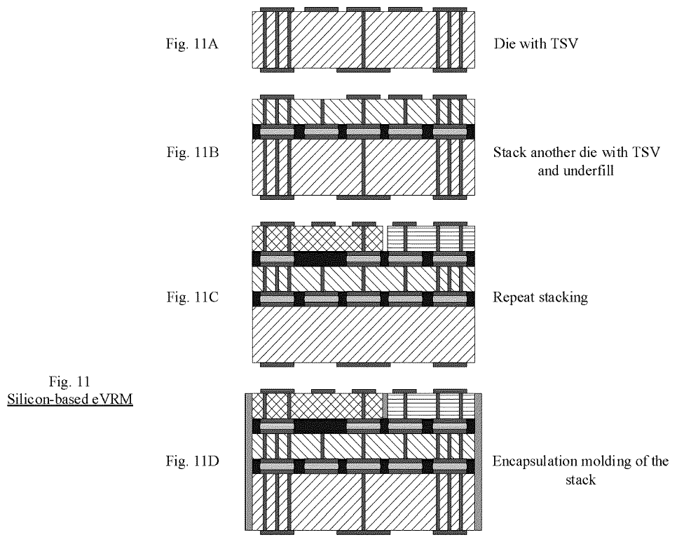

FIG. 11, comprising FIGS. 11A, 11B, 11C and 11D, illustrates, in stylized cross-section view, four other possible embodiments of silicon-based eVRM.

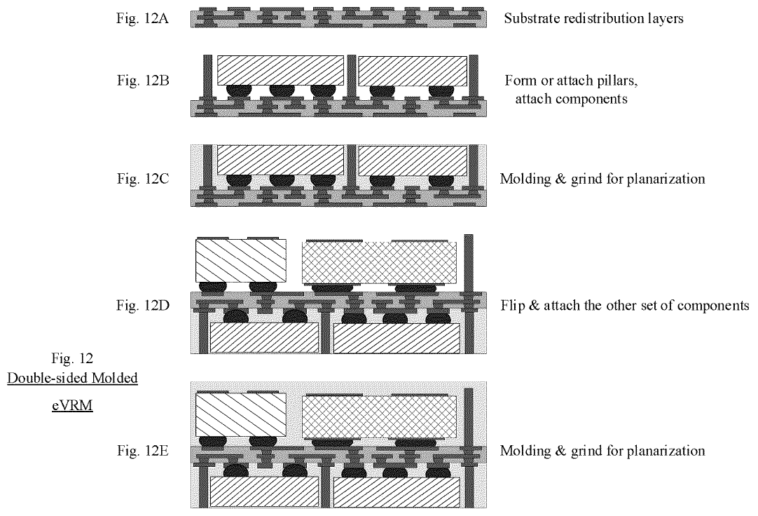

FIG. 12, comprising FIGS. 12A, 12B, 12C, 12D and 12E, illustrates, in stylized cross-section view, four possible embodiments of eVRM fabricated using a generic double-sided molding process.

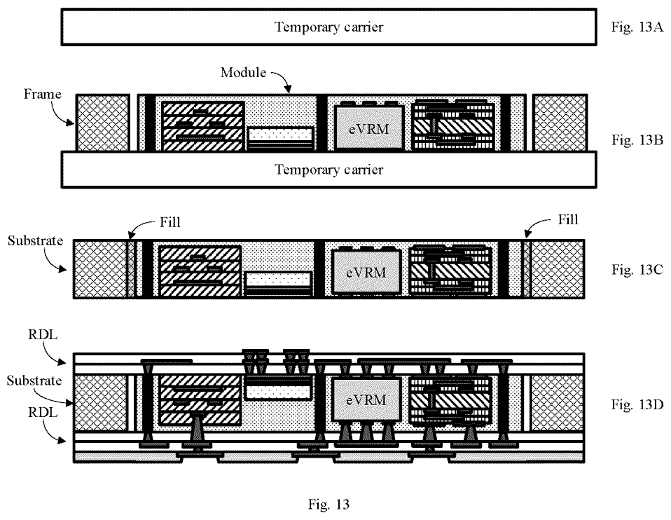

FIG. 13, comprising FIGS. 13A, 13B, 13C and 13D, depicts the process flow illustrated in FIG. 4 of the Ninth Patent Application in which e VRM fabricated in accordance with our invention are embedded in the course of manufacturing an advanced package substrate. In FIG. 13A, we fabricate a temporary carrier of convention form with a releasable film layer that will allow us to detach the carrier layer through standard debonding techniques. In FIG. 13B, we attach a frame (or core) according to the desired tile layout of the selected set of tiles, and then pick and place onto the temporary carrier an integrated module that we have previously fabricated comprising the selected tiles, each in a position defined by the desired tile layout. In FIG. 13C, we perform a conventional cavity fill and grind to final specifications. Finally, in FIG. 13D, we fabricate the desired upper/lower RDLs. At this point, the substrate is ready for bumping and die attach.

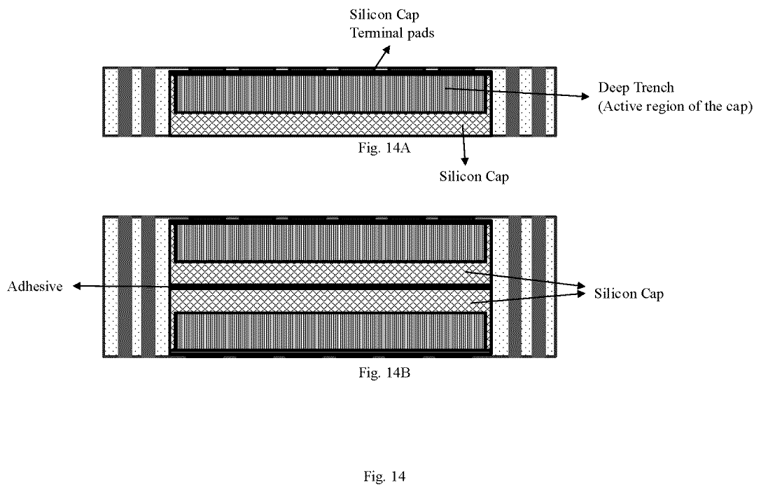

FIG. 14, comprising FIGS. 14A and 14B, illustrates possible embodiments of stand-alone, deep trench silicon capacitors adapted to be embedded into an advanced package substrate. In FIG. 14A, we have shown a single deep trench silicon capacitor, together with two pairs of copper pillars. In FIG. 14B, we have shown a back-to-back pair of such deep trench silicon capacitors, wherein all of the copper pillars pass, from bottom to top, completely through the module.

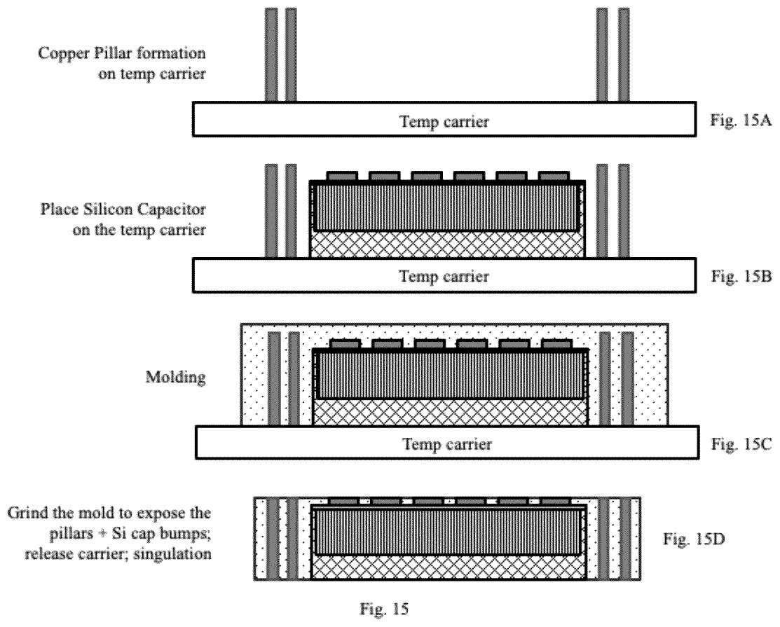

FIG. 15, comprising FIGS. 15A, 15B, 15C and 15D, illustrate one possible process for fabricating the deep trench silicon capacitors illustrated in FIG. 14.

The foregoing explanation described features of several embodiments so that those skilled in the art may better understand the scope of the invention. Those skilled in the art will appreciate that they may readily use the present disclosure as a basis for designing or modifying other processes and structures for carrying out the same purposes and/or achieving the same advantages of the embodiments herein. Such equivalent constructions do not depart from the spirit and scope of the present disclosure. Numerous changes, substitutions and alterations may be made without departing from the spirit and scope of the present invention.

Although illustrative embodiments of the invention have been described in detail with reference to the accompanying drawings, it is to be understood that the invention is not limited to those precise embodiments, and that various changes and modifications can be affected therein by one skilled in the art without departing from the scope of the invention as defined by the appended claims. Thus, it will be apparent to one of ordinary skill that this disclosure provides for improved method and apparatus for use in semiconductor packaging.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above-described embodiments, methods, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Terminology used in the present disclosure is intended to include all environments and alternate technologies that provide the same functionality described herein.

1. A voltage regulation module comprising:
a first capacitor having a first terminal and a second terminal, the first capacitor having:
a predetermined first dimension, X₁, in a first dimension, x, and
a predetermined second dimension, Y₁, in a second dimension, y, substantially orthogonal to the first dimension;
a semiconductor die comprising a voltage regulation control facility having an input terminal connected to the first terminal of the first capacitor and an output terminal, the die comprising a plane of predetermined thickness and having:
a predetermined third dimension, X₂, in the x dimension,
a predetermined fourth dimension, Y₂, in the y dimension,
a first side, and
a second side;
an inductor having a first terminal connected to the output terminal of the semiconductor die and a second terminal, the inductor having
a predetermined fifth dimension, X₃, in the x dimension, and
a predetermined sixth dimension, Y₃, in the y dimension; and
a second capacitor having a first terminal connected to the output terminal of the inductor and a second terminal, the first capacitor having
a predetermined seventh dimension, X₄, in the x dimension, and
a predetermined eighth dimension, Y₄, in the y dimension;
characterized in that:
the first capacitor is adapted to be located on a selected one of the first and second sides of the semiconductor die,
the inductor is adapted to be located on a selected one of the first and second sides of the semiconductor die, and
the second capacitor is adapted to be located on a selected one of the first and second sides of the semiconductor die;
wherein:
X₂ is no greater than X₁;
X₃ is no greater than X₁; and
X₄ is no greater than X₁; and
wherein, in a genus comprising at least four species:
in a selected first one of said species:
Y₂ is no greater than Y₁;
Y₃ is no greater than Y₁; and
Y₄ is no greater than Y₁;
in a selected second one of said species:
Y₁ is no greater than Y₂;
Y₃ is no greater than Y₂; and
Y₄ is no greater than Y₂;
in a selected third one of said species:
Y₁ is no greater than Y₃;
Y₂ is no greater than Y₃; and
Y₄ is no greater than Y₃; and
in a selected fourth one of said species:
Y₁ is no greater than Y₄;
Y₂ is no greater than Y₄; and
Y₃ is no greater than Y₄.

2. A voltage regulation module comprising:
a first capacitor having a first terminal and a second terminal, the first capacitor having:
a predetermined first dimension, X₁, in a first dimension, x, and
a predetermined second dimension, Y₁, in a second dimension, y, substantially orthogonal to the first dimension;
a semiconductor die comprising a voltage regulation control facility having an input terminal connected to the first terminal of the first capacitor and an output terminal, the die comprising a plane of predetermined thickness and having:
a predetermined third dimension, X₂, in the x dimension,
a predetermined fourth dimension, Y₂, in the y dimension,
a first side, and
a second side;
an inductor having a first terminal connected to the output terminal of the semiconductor die and a second terminal, the inductor having
a predetermined fifth dimension, X₃, in the x dimension, and
a predetermined sixth dimension, Y₃, in the y dimension; and
a second capacitor having a first terminal connected to the output terminal of the inductor and a second terminal, the first capacitor having
a predetermined seventh dimension, X₄, in the x dimension, and
a predetermined eighth dimension, Y₄, in the y dimension;
characterized in that:
the first capacitor is adapted to be located on a selected one of the first and second sides of the semiconductor die,
the inductor is adapted to be located on a selected one of the first and second sides of the semiconductor die, and
the second capacitor is adapted to be located on a selected one of the first and second sides of the semiconductor die; and
wherein:
X₁ is no greater than X₂;
X₃ is no greater than X₂; and
X₄ is no greater than X₂; and
wherein, in a genus comprising at least four species:
in a selected first one of said species:
Y₂ is no greater than Y₁;
Y₃ is no greater than Y₁; and
Y₄ is no greater than Y₁;
in a selected second one of said species:
Y₁ is no greater than Y₂;
Y₃ is no greater than Y₂; and
Y₄ is no greater than Y₂;
in a selected third one of said species:
Y₁ is no greater than Y₃;
Y₂ is no greater than Y₃; and
Y₄ is no greater than Y₃; and
in a selected fourth one of said species:
Y₁ is no greater than Y₄;
Y₂ is no greater than Y₄; and
Y₃ is no greater than Y₄.

3. A voltage regulation module comprising:
a first capacitor having a first terminal and a second terminal, the first capacitor having:
a predetermined first dimension, X₁, in a first dimension, x, and
a predetermined second dimension, Y₁, in a second dimension, y, substantially orthogonal to the first dimension;
a semiconductor die comprising a voltage regulation control facility having an input terminal connected to the first terminal of the first capacitor and an output terminal, the die comprising a plane of predetermined thickness and having:
a predetermined third dimension, X₂, in the x dimension,
a predetermined fourth dimension, Y₂, in the y dimension,
a first side, and
a second side;
an inductor having a first terminal connected to the output terminal of the semiconductor die and a second terminal, the inductor having
a predetermined fifth dimension, X₃, in the x dimension, and
a predetermined sixth dimension, Y₃, in the y dimension; and
a second capacitor having a first terminal connected to the output terminal of the inductor and a second terminal, the first capacitor having
a predetermined seventh dimension, X₄, in the x dimension, and
a predetermined eighth dimension, Y₄, in the y dimension;
characterized in that:
the first capacitor is adapted to be located on a selected one of the first and second sides of the semiconductor die,
the inductor is adapted to be located on a selected one of the first and second sides of the semiconductor die, and
the second capacitor is adapted to be located on a selected one of the first and second sides of the semiconductor die; and
wherein:
X₁ is no greater than X₃;
X₂ is no greater than X₃; and
X₄ is no greater than X₃ and
wherein, in a genus comprising at least four species:
in a selected first one of said species:
Y₂ is no greater than Y₁;
Y₃ is no greater than Y₁; and
Y₄ is no greater than Y₁;
in a selected second one of said species:
Y₁ is no greater than Y₂;
Y₃ is no greater than Y₂; and
Y₄ is no greater than Y₂;
in a selected third one of said species:
Y₁ is no greater than Y₃;
Y₂ is no greater than Y₃; and
Y₄ is no greater than Y₃; and
in a selected fourth one of said species:
Y₁ is no greater than Y₄;
Y₂ is no greater than Y₄; and
Y₃ is no greater than Y₄.

4. A voltage regulation module comprising:
a first capacitor having a first terminal and a second terminal, the first capacitor having:
a predetermined first dimension, X₁, in a first dimension, x, and
a predetermined second dimension, Y₁, in a second dimension, y, substantially orthogonal to the first dimension;
a semiconductor die comprising a voltage regulation control facility having an input terminal connected to the first terminal of the first capacitor and an output terminal, the die comprising a plane of predetermined thickness and having:
a predetermined third dimension, X₂, in the x dimension,
a predetermined fourth dimension, Y₂, in the y dimension,
a first side, and
a second side;
an inductor having a first terminal connected to the output terminal of the semiconductor die and a second terminal, the inductor having
a predetermined fifth dimension, X₃, in the x dimension, and
a predetermined sixth dimension, Y₃, in the y dimension; and
a second capacitor having a first terminal connected to the output terminal of the inductor and a second terminal, the first capacitor having
a predetermined seventh dimension, X₄, in the x dimension, and
a predetermined eighth dimension, Y₄, in the y dimension;
characterized in that:
the first capacitor is adapted to be located on a selected one of the first and second sides of the semiconductor die,
the inductor is adapted to be located on a selected one of the first and second sides of the semiconductor die, and
the second capacitor is adapted to be located on a selected one of the first and second sides of the semiconductor die; and
wherein:
X₁ is no greater than X₄;
X₂ is no greater than X₄; and
X₄ is no greater than X₄; and
wherein, in a genus comprising at least four species:
in a selected first one of said species:
Y₂ is no greater than Y₁;
Y₃ is no greater than Y₁; and
Y₄ is no greater than Y₁;
in a selected second one of said species:
Y₁ is no greater than Y₂;
Y₃ is no greater than Y₂; and
Y₄ is no greater than Y₂;
in a selected third one of said species:
Y₁ is no greater than Y₃;
Y₂ is no greater than Y₃; and
Y₄ is no greater than Y₃; and
in a selected fourth one of said species:
Y₁ is no greater than Y₄;
Y₂ is no greater than Y₄; and
Y₃ is no greater than Y₄.

5. A voltage regulation module comprising:
a first capacitor having a first terminal and a second terminal, the first capacitor having:
a predetermined first dimension, X₁, in a first dimension, x, and
a predetermined second dimension, Y₁, in a second dimension, y, substantially orthogonal to the first dimension;
a semiconductor die comprising a voltage regulation control facility having an input terminal connected to the first terminal of the first capacitor and an output terminal, the die comprising a plane of predetermined thickness and having:
a predetermined third dimension, X₂, in the x dimension,
a predetermined fourth dimension, Y₂, in the y dimension,
a first side, and
a second side;
an inductor having a first terminal connected to the output terminal of the semiconductor die and a second terminal, the inductor having
a predetermined fifth dimension, X₃, in the x dimension, and
a predetermined sixth dimension, Y₃, in the y dimension; and
a second capacitor having a first terminal connected to the output terminal of the inductor and a second terminal, the first capacitor having
a predetermined seventh dimension, X₄, in the x dimension, and
a predetermined eighth dimension, Y₄, in the y dimension;
characterized in that:
the first capacitor is adapted to be located on a selected one of the first and second sides of the semiconductor die,
the inductor is adapted to be located on a selected one of the first and second sides of the semiconductor die, and
the second capacitor is adapted to be located on a selected one of the first and second sides of the semiconductor die; and
wherein, in a family comprising at least four genera:
in a selected first genus of said genera:
X₂ is no greater than X₁;
X₃ is no greater than X₁; and
X₄ is no greater than X₁; and
wherein the first genus comprises at least four species:
in a selected first one of said species:
Y₂ is no greater than Y₁;
Y₃ is no greater than Y₁; and
Y₄ is no greater than Y₁;
in a selected second one of said species:
Y₁ is no greater than Y₂;
Y₃ is no greater than Y₂; and
Y₄ is no greater than Y₂;
in a selected third one of said species:
Y₁ is no greater than Y₃;
Y₂ is no greater than Y₃; and
Y₄ is no greater than Y₃; and
in a selected fourth one of said species:
Y₁ is no greater than Y₄;
Y₂ is no greater than Y₄; and
Y₃ is no greater than Y₄.
in a selected second genus of said genera:
X₁ is no greater than X₂;
X₃ is no greater than X₂; and
X₄ is no greater than X₂; and
wherein the second genus comprises at least four species:
in a selected fifth one of said species:
Y₂ is no greater than Y₁;
Y₃ is no greater than Y₁; and
Y₄ is no greater than Y₁;
in a selected sixth one of said species:
Y₁ is no greater than Y₂;
Y₃ is no greater than Y₂; and
Y₄ is no greater than Y₂;
in a selected seventh one of said species:
Y₁ is no greater than Y₃;
Y₂ is no greater than Y₃; and
Y₄ is no greater than Y₃; and
in a selected eighth one of said species:
Y₁ is no greater than Y₄;
Y₂ is no greater than Y₄; and
Y₃ is no greater than Y₄.
in a selected third genus of said genera:
X₁ is no greater than X₃;
X₂ is no greater than X₃; and
X₄ is no greater than X₃; and
wherein the third genus comprises at least four species:
in a selected ninth one of said species:
Y₂ is no greater than Y₁;
Y₃ is no greater than Y₁; and
Y₄ is no greater than Y₁;
in a selected tenth one of said species:
Y₁ is no greater than Y₂;
Y₃ is no greater than Y₂; and
Y₄ is no greater than Y₂;
in a selected eleventh one of said species:
Y₁ is no greater than Y₃;
Y₂ is no greater than Y₃; and
Y₄ is no greater than Y₃; and
in a selected twelfth one of said species:
Y₁ is no greater than Y₄;
Y₂ is no greater than Y₄; and
Y₃ is no greater than Y₄; and
in a selected fourth genus of said genera:
X₁ is no greater than X₄;
X₂ is no greater than X₄; and
X₃ is no greater than X₄; and
wherein the fourth genus comprises at least four species:
in a selected thirteenth one of said species:
Y₂ is no greater than Y₁;
Y₃ is no greater than Y₁; and
Y₄ is no greater than Y₁;
in a selected fourteenth one of said species:
Y₁ is no greater than Y₂;
Y₃ is no greater than Y₂; and
Y₄ is no greater than Y₂;
in a selected fifteenth one of said species:
Y₁ is no greater than Y₃;
Y₂ is no greater than Y₃; and
Y₄ is no greater than Y₃; and
in a selected sixteenth one of said species:
Y₁ is no greater than Y₄;
Y₂ is no greater than Y₄; and
Y₃ is no greater than Y₄.
